(19) United States
(12) Patent Application Publication
(10) Pub. No.: US 2005/0082035 A1
(43) Pub. Date: Apr. 21, 2005

(54) Heat dissipating apparatus

(76) Inventors: Bisuwasu Debashisu, Shiki-shi (JP); Tomonao Takamatsu, Tokyo (JP); Katsumi Hisano, Matsudo-shi (JP); Hideo Iwasaki, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/925,997

(22) Filed: Aug. 26, 2004

(30) Foreign Application Priority Data
Aug. 28, 2003 (JP) 2003-304916

(51) Int. Cl. H05K 7/20

(52) U.S. Cl. 165/80.3; 361/687

(57) ABSTRACT

One surface of a base section having an open portion forming an inlet port of a fluid is thermally connected to a target module to be cooled. Pluralities of fins arranged in parallel are mounted on the other surface of a base section in a direction substantially perpendicular to the base section. A fan is arranged to permit the fluid to flow through the clearance between the adjacent fins. A wall section open to the inlet port of the fluid is mounted on the base section. A part of the wall section constitutes a detachable lid section. A partition plate having through-holes formed therein is arranged between the base section and the lid section so as to divide the space between the base section and the lid section into two fluid flowing channels consisting of a main flowing channel and an auxiliary flowing channel.

### CROSS-REFERENCE TO RELATED APPLICATIONS

This application is based upon and claims the benefit of priority from prior Japanese Patent Application No. 2003-304916, filed Aug. 28, 2003, the entire contents of which are incorporated herein by reference.

### BACKGROUND OF THE INVENTION

1. Field of the Invention

The present invention relates to a heat dissipating apparatus for dissipating heat from a target module to be cooled, particularly, to a heat dissipating apparatus, in which a fluid is supplied into the fluid flowing channel within a heat dissipating apparatus, and a heat exchange is carried out between the wall surface of the channel and the fluid supplied into the channel so as to dissipate heat released from the target module to be cooled.

2. Description of the Related Art

A heat dissipating apparatus utilizing a heat exchanger is widely known in the art. In recent years, many apparatuses are being made thinner and more compact. In this connection, the amount of heat generation relative to the size of the target module to be cooled, which is included in the apparatus, is increased. It is widely known in the art that, in order to improve the cooling effect of the apparatus, a fluid is supplied into heat dissipating apparatus. However, the conventional heat dissipating apparatus of this type gives rise to the problem that, in accordance with the flow of fluid within the channel from the upstream side toward the downstream side, a boundary layer grows in the fluid so as to impair heat exchange function performed between the wall of the fluid flowing channel and the fluid. The boundary layer is a fluid layer in which the fluid is flowing at a reduced velocity, which is formed immediately adjacent to the surface of a solid part.

In the conventional heat dissipating apparatus, the influence of the boundary layer is suppressed by generating turbulence in the flow of fluid within the fluid flowing channel so as to suppress the growth of the boundary layer in the fluid flowing within the fluid flowing channel. In heat dissipating apparatus disclosed in, for example, Japanese Patent Disclosure (Kokai) No. 63-17393, a projection is formed on the wall of the fluid flowing channel so as to suppress the growth of the boundary layer in the fluid flowing within the channel. Also, in heat dissipating apparatus disclosed in, for example, Japanese Patent Disclosure No. 2001-127223, a rib is formed in a part of heat-dissipating fin so as to suppress the growth of the boundary layer in the fluid flowing within the fluid flowing channel. Further, in heat dissipating apparatus disclosed in, for example, Japanese Patent Disclosure No. 11-338284, which is intended to improve heat dissipating efficiency, a rib having an angle of attack relative to the flowing-direction of the fluid is arranged so as to suppress the growth of the boundary layer in the fluid flowing within the fluid flowing channel.

The heat dissipating apparatuses disclosed in each of the prior arts quoted above, in which a protruding portion is formed for promoting heat transfer, certainly permits producing a sufficient effect of suppressing the growth of the boundary layer. However, the supply section for supplying the fluid is required to have a large capacity. It is certainly possible to impart a large capacity to the fluid supply section by, for example, enlarging the size or increasing the rotating speed of the rotary vane. However, the particular measure results in the increase in size of heat dissipating apparatus. Also, it is necessary to solve the noise problem generated in heat dissipating apparatus.

### BRIEF SUMMARY OF THE INVENTION

An object of the present invention is to provide a heat dissipating apparatus, which permits miniaturizing the apparatus, permits suppressing noise generation, and also permits improving the cooling efficiency.

According to a first aspect of the present invention, there is provided an apparatus for dissipating heat from a target module to be cooled, comprising:
an envelope having a first flowing channel in which a fluid flows in a first direction and a heat transfer surface along which heat is transferred from the target module to the fluid flows; and
a jet stream supply section configured to supply a jet stream to the fluid flowing in the first flowing channel in a second direction differing from the first direction so as to generate turbulence in the flow of fluid in the first flowing channel, thereby suppressing the growth of a boundary layer in the fluid within the fluid flowing channel.

Also, according to a second aspect of the present invention, there is provided a heat dissipating apparatus for dissipating heat from a target module to be cooled, comprising:
a supply unit configured to supply a flowing fluid; and
an envelope having inlet and outlet ports, configured to guide the flowing fluid from the inlet port to the outlet port, including;
a base section thermally coupled to the target module, configured to conduct heat from the target module;
a lid section configured to defined a flowing space on the base section between the inlet and outlet ports;
a partition plate having a plurality of holes, configured to partition the flowing space into first and second flowing channels to separate the flowing fluid into first and second fluid streams, part of the second fluid stream being jetted into the first fluid stream through the respective holes to generate turbulence in the first fluid stream in the first flowing channel; and
a plurality of fin sections arranged in the first flowing channel on the base section and extended in a direction substantially perpendicular to the base section and between the inlet and outlet ports.

Further, according to a second aspect of the present invention, there is provided a method for cooling a target module, comprising:
allowing a main fluid stream to flow into a main flowing channel of an envelope so as to transfer heat released from the target module to be cooled to the main fluid stream; and
supplying a jet stream into the main fluid stream flowing within the main flowing channel so as to bring about turbulence in the main fluid stream, thereby suppressing the growth of a boundary layer in the main fluid stream within the main flowing channel.

### BRIEF DESCRIPTION OF THE SEVERAL VIEWS OF THE DRAWING

FIG. 1 is an oblique view schematically showing the configuration of a heat dissipating apparatus according to a first embodiment of the present invention;

FIG. 2 is a cross-sectional view schematically showing the configuration of heat dissipating apparatus shown in FIG. 1 and also showing schematically the configuration of the fluid flowing channel included in heat dissipating apparatus;

FIG. 3 is an oblique view schematically showing the outer appearance of a heat dissipating apparatus according to a second embodiment of the present invention;

FIG. 4 is a plan view schematically showing the internal structure of heat dissipating apparatus shown in FIG. 3;

FIG. 5 is a vertical cross-sectional view schematically showing the internal structure of heat dissipating apparatus shown in FIG. 3;

FIG. 6 is an oblique view schematically showing in a magnified fashion a part of heat dissipating apparatus shown in FIG. 3;

FIG. 7 is a plan view schematically showing in a magnified fashion the internal structure of a part of a heat dissipating apparatus according to a third embodiment of the present invention;

FIG. 8 is a plan view schematically showing in a magnified fashion the internal structure of a part of heat dissipating apparatus according to a modification of the third embodiment of the present invention shown in FIG. 7;

FIG. 9 is a plan view schematically showing the internal structure of a heat dissipating apparatus according to a fourth embodiment of the present invention;

FIG. 10 is a vertical cross-sectional view schematically showing the configuration of heat dissipating apparatus according to the fourth embodiment of the present invention shown in FIG. 9;

FIG. 11A shows comparative duct configuration of heat dissipating apparatus, which is not provided with a separation wall;

FIG. 11B shows vorticity distribution in duct configurations shown in FIG. 11A;

FIG. 11C shows temperature distribution in duct configurations shown in FIG. 11A;

FIG. 11D shows heat transfer distribution in duct configurations shown in FIG. 11A;

FIG. 12A shows the duct configuration of heat dissipating apparatus according to the present invention, which is provided with a separating wall near the top wall;

FIG. 12B shows vorticity distribution in duct configurations shown in FIG. 12A;

FIG. 12C shows temperature distribution in duct configurations shown in FIG. 12A; and

FIG. 12D shows heat transfer distribution in duct configurations shown in FIG. 12A.

### DETAILED DESCRIPTION OF THE INVENTION

The heat dissipating apparatus according to an embodiment of the present invention will now be described with reference to the accompanying drawings.

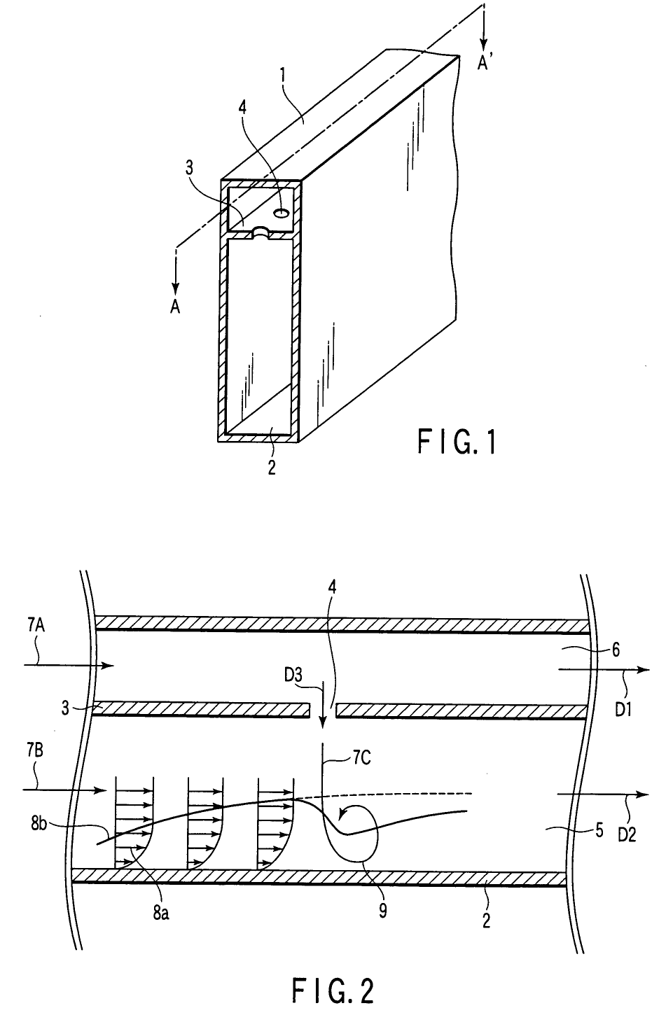

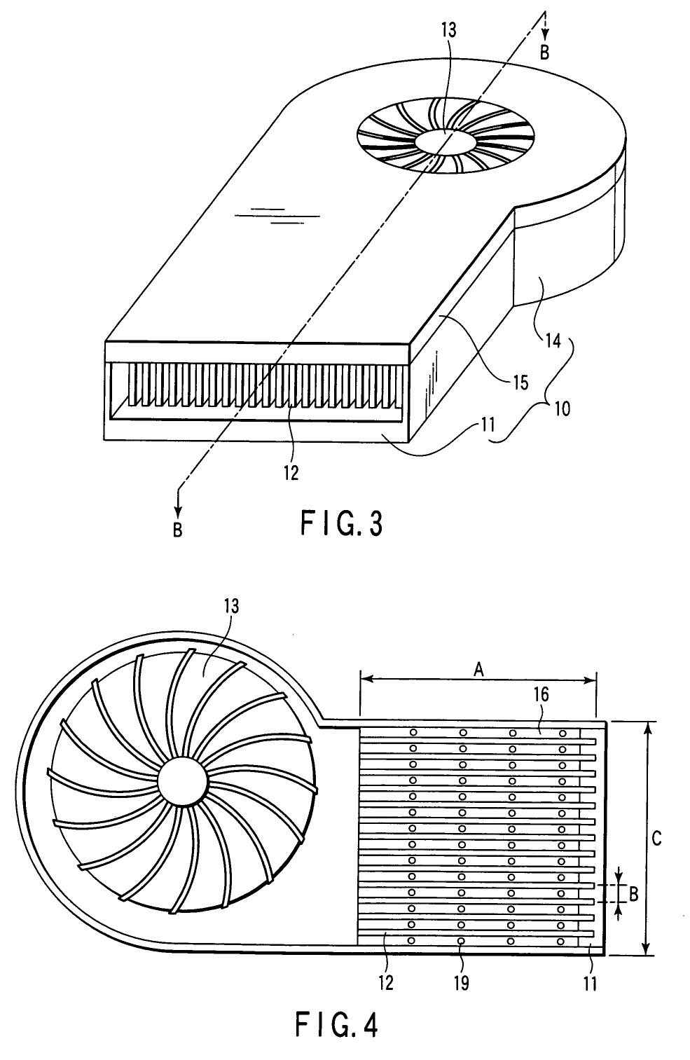

FIG. 1 is an oblique view schematically showing a configuration of a heat dissipating apparatus according to a first embodiment of the present invention, and FIG. 2 is a cross-sectional view schematically showing the configuration of heat dissipating apparatus shown in FIG. 1 and also showing schematically the configuration of the fluid flowing channel included in heat dissipating apparatus.

A rectangular duct 1 having a rectangular cross section, which constitutes an envelope having an inlet port and an outlet port, is formed of a metal having relatively large heat conductivity such as aluminum or copper. A fluid flowing space within which flows a fluid is formed within the rectangular duct 1. A heat transfer surface 2 corresponding to the bottom surface of the rectangular duct 1 is thermally coupled to the target module to be cooled or thermally in contact with the target module to be cooled (not shown). The heat of the target module to be cooled is transferred through heat transfer surface 2 into the rectangular duct 1 so as to exchange heat with the fluid flowing within the rectangular duct 1. A partition plate 3 serving to partition the fluid flowing space into two fluid flowing channels 5, 6 is arranged within the rectangular duct 1. A plurality of through-holes 4 is formed as a jet stream supply section for generating a jet stream in the partition plate 3.

FIG. 2 is a cross-sectional view along the line A-A shown in FIG. 1. As shown in FIGS. 1 and 2, the fluid flowing channels are formed within the rectangular duct 1, which is separated by the partition plate 3 into a first channel corresponding to a main flowing channel 5 and a second channel corresponding to an auxiliary flowing channel 6. A fluid stream is guided in the inlet port and is separated into auxiliary and main fluid streams 7A, 7B. The main fluid stream 7B corresponding to a first stream flows through the main fluid flowing channels 5 in a first flowing-directions D2 to transfers heat released from heat transfer surface 2. The auxiliary fluid stream 7A corresponding to a second stream flows through auxiliary flowing channel 6 in a first flowing-directions D1.

The main fluid stream 7B flows smoothly along the wall of the main flowing channel 5. However, since the main fluid stream 7B has a viscosity, the flowing-velocity of the main fluid stream 7B is low in a region close to the wall of the main flowing channel 5 and is gradually lowered further toward the wall of the main flowing channel 5 so as to be lowered to zero on the wall of the main flowing channel 5. Arrows 8a shown in FIG. 2 denote the velocity vectors of the main fluid stream 7B. A region in which the flowing-velocity of the main fluid stream 7B is low, i.e., a boundary layer 8b, is developed (or grows) during flow of main fluid stream 7B from the upstream side toward the downstream side. In the boundary layer 8b, the mixing of the main fluid stream 7B with another fluid stream 7C flowing in a second direction D3 differing from the first flowing-directions D1, D2 of the main fluid stream 7B is suppressed so as to lower heat conductivity. In other words, heat conductivity is gradually lowered during flow of main fluid stream 7B from the upstream side toward the downstream side.

The auxiliary fluid stream 7A also flows into the auxiliary flowing channel 6. It should be noted in this connection that the inner pressure of the auxiliary flowing channel 6 could be made higher than the inner pressure of the main flowing channel 5 by closing the outlet port of the auxiliary flowing channel 6 on the right side in FIG. 2. It follows that the auxiliary fluid stream 7A flows from the auxiliary flowing channel 6 through the through-holes 4 into the main flowing channel 5 in a direction differing D3 from the flowing-direction D2 of the main fluid stream 7B flowing within the main flowing channel 5. In other words, each of the through-holes 4 acts as a jest stream supply section for supplying a jet stream of the auxiliary fluid stream 7A through the through hole 4 from the auxiliary flowing channel 6 into the main flowing channel 5 so as to bring about turbulence 9 of the main fluid stream 7B. The main fluid stream 7B flowing within the main flowing channel 5 is stirred by the turbulence 9 of the fluid so as to suppress the growth of the boundary layer 8b. Also, the mixing of the main fluid stream 7B is promoted by the turbulence 9 of the fluid.

As described above, the first embodiment of the present invention makes it possible to provide a heat dissipating apparatus, which permits suppressing the growth of the boundary layer in the fluid flowing within the fluid flowing channel without arranging a protruding heat transfer promoting section, which causes pressure loss, so as to enable heat dissipating apparatus to exhibit a high heat dissipating effect.

A heat dissipating apparatus according to a second embodiment of the present invention will now be described with reference to FIGS. 3 to 6.

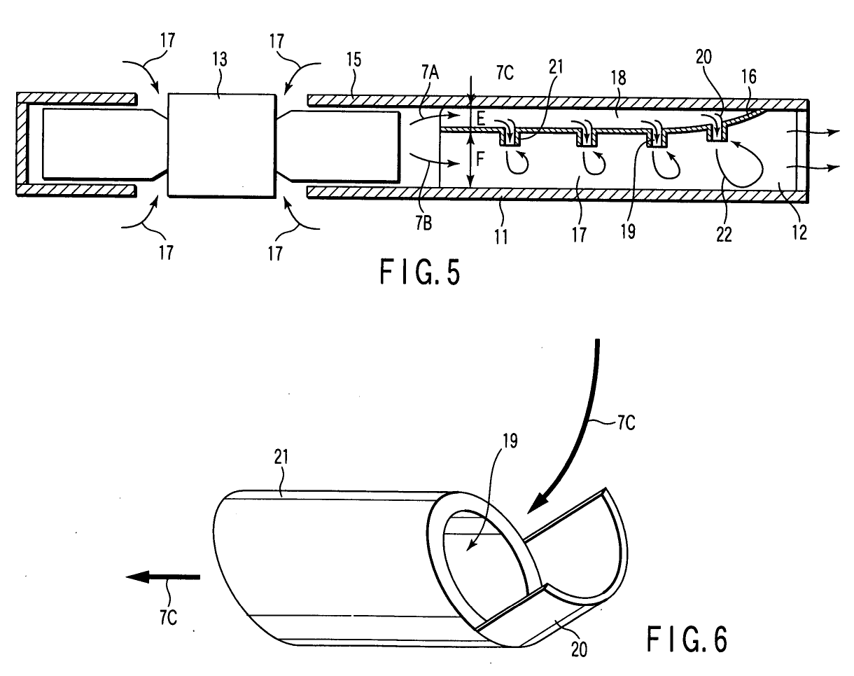

FIG. 3 is an oblique view schematically showing the outer appearance of heat dissipating apparatus according to the second embodiment of the present invention. FIG. 4 schematically shows the inner structure of heat dissipating apparatus shown in FIG. 3. Further, FIG. 5 is a cross section view along the line B-B shown in FIG. 3. Incidentally, a lid section 15, which is referred to herein later, is omitted from FIG. 4 for clearly showing the inner structure of heat dissipating apparatus.

In heat dissipating apparatus according to the second embodiment of the present invention, an envelope comprises a flat plate-shaped base section 11, a wall section 14 erected in a direction substantially perpendicular to the base section 11 and extending upward in a manner to surround the outer circumferential surface of the base section 11, and a lid section closing the wall section 14. In other words, a box structure is so formed and defined by the base section 11 and the wall section 14 as to have an inlet port and an outlet port of the fluid streams 7A, 7B. The box structure is also closed by the detachable lid section 15 to form the envelope 10. The target module to be cooled (not shown) such as a central processing unit (CPU) of a personal computer is thermally coupled to the outer bottom surface of the base section 11. Also, a plurality of fins 12, which are parallel to each other, are mounted on the inner surface of the base section 11 such that the fins 12 extend upward in a direction substantially perpendicular to the base section 11. A fan 13 acting as a supply unit for supplying a fluid, such as an electrical centrifugal fan, is mounted on the base section 11, and an inlet port of the fluid is formed in the lid section 15 in a manner to face the fan 13. In accordance with rotation of the fan 13, the fluid flows from the inlet port into the fluid flowing channel formed between the adjacent fins 12, and the fluid flowing through the flowing channel is discharged to the outside through an outlet port of the envelope 10.

A method of manufacturing the envelope 10 will now be exemplified.

Specifically, the base section 11 and the fins 12 of the envelope 10 excluding the portion where the fan 13 is to be formed are formed by using, for example, a metal having a high heat conductivity such as aluminum or copper. Extrusion molding is employed in general in the case of using aluminum, and cutting is employed in general in the case of using copper for forming the base section 11 and the fins 12. Alternatively, it is also possible to form the base section 11 and the fins 12 of the envelope 10 by combining flat plates. On the other hand, the portion where the fan 13 is to be housed or the lid section 15 is formed by injection a plastic material such as polycarbonate. Also, it is possible to form integrally the base section 11, the fins 12 and the housing portion of the fan 13 by, for example, a casting technology such as die-casting.

As shown in FIG. 5, the partition plate 16 is arranged between the base section 11 and the lid section 15 so as to partition the free space between the base section 11 and the lid section 15 into a first channel, which is a main flowing channel 17, and a second channel, which is an auxiliary flowing channel. The partition plate 16 extends from the upstream side of the main fluid stream 7B, i.e., from a region in the vicinity of the edge of the fin 12 on the side of the fan 13, to the downstream side of the main fluid stream 7B, i.e., to the edge of the fin 12 on the side of the outlet port. As shown in the drawing, the partition plate 16 is curved such that the partition plate 16 extends closer to the lid section 15 in the flowing-direction D2 of the main fluid stream 7B toward the downstream side so as to reach finally the lid section 15. It follows that the cross-sectional area of the auxiliary flowing channel 18 in a direction perpendicular to the flowing-direction of the main fluid stream 7B is gradually decreased toward the downstream side in the flowing-direction of the main fluid stream 7B such that the edge portion of the partition plate 16 on the side of the outlet port is brought into contact with the lid section 15 so as to close the outlet side of the auxiliary flowing channel 18.

In the second embodiment of the present invention shown in the drawings, the fin 12 extends from the base section 12 through the partition plate 16 so as to reach the lid section 15. Alternatively, it is possible for the envelope 10 to be constructed as follows:

(1) The structure that the fins 12 are allowed to extend from the base section 11 through the partition plate 16 so as to reach a region forward of the lid section 15.

(2) The structure that the fins 12 are allowed to extend to reach the partition plate 16, but are not allowed extending through the partition plate 16.

(3) The structure that some of the fins 12 are allowed to extend through the partition plate 16 so as to reach the inner region of the auxiliary flowing channel 18, and the other fins 12 are allowed to extend to reach the partition plate 16.

It is also possible to modify the configuration of the envelope 10 in various fashions in addition to the modifications given above. It suffices for the envelope 10 to be constructed such that the inner region of the envelope 10 is partitioned by the partition plate 16 into the space of the main flowing channel and the space of the auxiliary flowing channel, and that the space of the main flowing channel is partitioned by the fins 12 into a plurality of main flowing channels, and a single or a plurality of auxiliary flowing channels are defined in the space of the auxiliary flowing channel.

As apparent from FIGS. 4 and 6, a large number of through-holes 19 are formed in the partition plate 16 such that a plurality of through-holes 19 are arranged in a region positioned between adjacent fins 12. Each of the through-holes 19 has an elliptical cross-sectional shape, with the major axis of the ellipse being formed in the flowing-direction of the main fluid stream 7B. As shown in FIG. 4, the through-holes 19 are not arranged in the vicinity of the inlet port of the main flowing channel 17 and are arranged in the downstream region a prescribed distance away from the inlet port of the main flowing channel 17 in the flowing-direction of the fluid. It should be noted in this connection that the boundary layer grows in accordance with flow of main fluid stream 7B toward the downstream side within the main flowing channel 17. Such being the situation, the particular arrangement of the through-holes 19 is effective for suppressing the growth of the boundary layer.

As shown in FIG. 6, a projection, e.g., a guide vane 20 is formed in the edge portion, on the downstream side in the flowing-direction of the main fluid stream 7B, of the through-hole 19. The guide vane 20 is formed on the side of the auxiliary flowing channel 18 positioned above the partition plate 16. Incidentally, the partition plate 16 is not shown in FIG. 6 in order to show the configuration of the guide vane 20 and a guide pipe 20 referred to herein later. The guide vane 20, which is arranged in the edge portion, on the downstream side, of the elliptical through-hole 19, is curved along a region substantially half the edge portion or small than half the edge portion of the elliptical through-hole 19 so as to be inclined toward the upstream side from the edge portion of the elliptical through-hole 19.

Also, a tubular portion including the through-hole 19, e.g., a guide pipe 21, is formed in the partition plate 16 such that the guide pipe 21 projects downward from the partition plate 16 toward the main flowing channel 17, as shown in FIG. 6. The guide pipe 21 is arranged to permit its open portion to be positioned such that a jet stream is spurted from the guide pipe 21 in a direction differing from the flowing-direction of the main fluid stream 7B. In the embodiment shown in FIG. 5, the open portion of the guide pipe 21 is positioned to permit a jet stream to be spurted from the guide pipe 21 in a direction substantially perpendicular to the flowing-direction of the main fluid stream 7B.

In heat dissipating apparatus of the configuration described above, heat released from the target module to be cooled is transferred to the base section 11, and heat transferred to the base section 11 is transferred from another surface of the base section 11 into the main fluid stream 7B so as to be dissipated into the main fluid stream 7B. To be more specific, heat transferred to the base section 11 is further transferred to reach the fin 12 and, then, transferred into the main fluid stream 7B through the fin 12 so as to be dissipated into the main fluid stream 7B. It follows that the fin 12 performs the function of a heat-dissipating surface together with the base section 11 so as to enlarge the surface area for dissipating heat, which is included in heat dissipating apparatus.

The partition plate 16 partitions the fluid flowing path into which the fluid flow is guided from the fan 13 into the main flowing channel 17 and the auxiliary flowing channel 18, and the fluid flow is separated into two streams 7A, 7B guided in the main flowing channel 17 and the auxiliary flowing channel 18. As described previously, the outlet side of the auxiliary flowing channel 18 is closed, with the result that the inner pressure of the auxiliary flowing channel 18 is rendered higher than the inner pressure of the main flowing channel 17. It follows that the auxiliary fluid stream 7A flows through the through-hole 19 so as to be spurted into the main flowing channel 17. It should be noted that the main fluid stream 7B flowing within the auxiliary flowing channel 19 is guided toward the through-hole 19 by the guide vane 20 arranged within the auxiliary flowing channel 18, and the guide pipe 21 permits the main fluid stream 7B flowing through the through-hole 19 to be spurted from the open portion of the guide pipe 21 so as to form a jet stream. As described previously, the jet stream is spurted in a direction differing from the flowing-direction of the main fluid stream 7B within the main flowing channel 17. It follows that a turbulence 22 is formed in the main fluid stream 7B flowing within the main flowing channel 17 by the jet stream spurted into the main fluid stream 7B. The turbulence 22 of the fluid causes the main fluid stream 7B flowing within the main flowing channel 17 to be agitated so as to suppress the growth of the boundary layer. Also, the mixing of the main fluid stream 7B is promoted.

As described above, in heat dissipating apparatus according to the second embodiment of the present invention, the fins 12 finely partition the main flowing channel 17. Also, the surface of the fin 12 performs the function of heat-dissipating surface. It follows that the jet stream spurted from the through-hole 19 serves to suppress not only the growth of the boundary layer in the vicinity of the base section 11 but also the growth of the boundary layer in the vicinity of the fin 12 so as to obtain a high heat dissipating effect.

It should also be noted that the cross-sectional area of the auxiliary flowing channel 18 in a direction perpendicular to the flowing-direction of the main fluid stream 7B is gradually decreased toward the downstream side of the main fluid stream 7B. As a result, the main fluid stream 7B smoothly flows in the auxiliary flowing channel 18 without stagnating so as to decrease the pressure loss within the auxiliary flowing channel 18. The decrease of the pressure loss makes it possible for the capability required for the fan 13 to be lowered so as to suppress noise generation from heat dissipating apparatus and to miniaturize heat-dissipating apparatus.

Also, the guide vane 20 and the guide pipe 21 serve to change the direction of the main fluid stream 7B flowing within the auxiliary flowing channel 18 so as to permit the main fluid stream 7B to flow smoothly and also serve to straighten the flow of main fluid stream 7B. It follows that the flowing-velocity of the main fluid stream 7B spurted from the through-hole 19 is increased, and the function of suppressing the growth of the boundary layer is promoted so as to obtain a higher heat dissipating effect.

What should also be noted is that the through-hole 19 or the open portion of the guide pipe 21 is shaped elliptical with the flowing-direction of the main fluid stream 7B forming the major axis of the ellipse. As a result, it is possible to extend the mixing time between the fluid flowing within the main flowing channel 17 and the jet stream spurted from the auxiliary flowing channel 18 through the through-hole 19 or the guide pipe 21. It follows that the function of suppressing the growth of the boundary layer is promoted so as to obtain a higher heat dissipating effect.

Incidentally, heat dissipating apparatus of the configuration described above has dimensions A, B and C given in FIG. 4 and dimensions F and E given in FIG. 5. These dimensions are defined such that the length A of the fin 12 is 70 mm (A=70 mm), the distance B between the adjacent fins 12 is 3 mm (B=3 mm), the width C of the open portion of heat dissipating apparatus is 50 mm (C=50 mm), the minimum height F of the main flowing channel is 8 mm (F=8 mm), and the maximum height E of the auxiliary flowing channel is 2 mm (E=2 mm). In heat dissipating apparatus having the dimensions given above, it is possible to achieve a high heat conductivity with a small pressure loss as shown in Table 1 according to the analysis of the numerical values obtained by solving a three dimensional Navier-Stokes equation.

TABLE 1

| | No measure | Convex heat | |
|---|---|---|---|
| | against | transfer | |
| | boundary | promoting | Second |
| | layer | section | embodiment |
| Heat | 100% | 140% | 140% |
| conductivity | | | |
| Pressure loss | 100% | 200% | 120% |

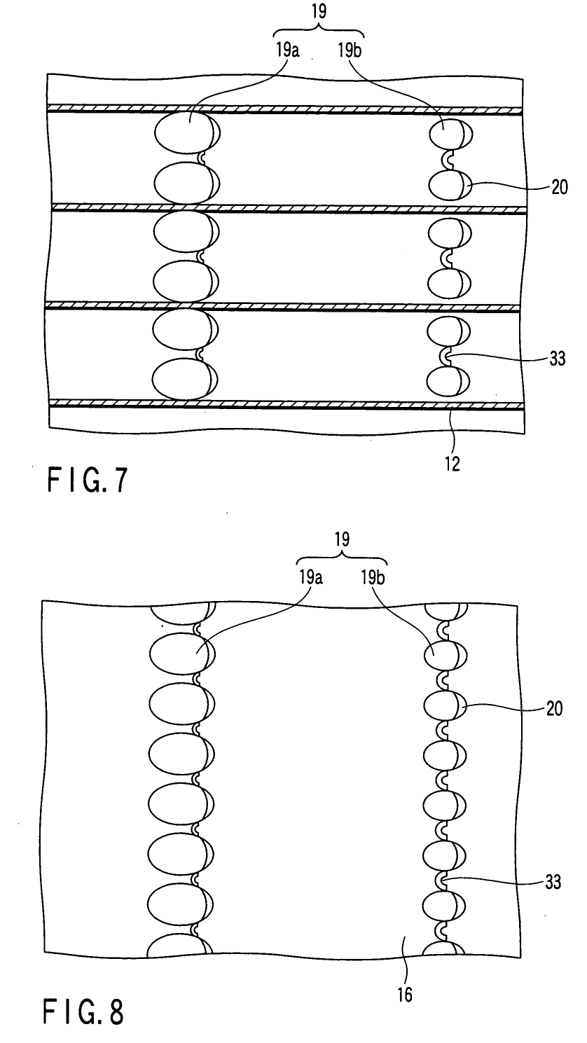

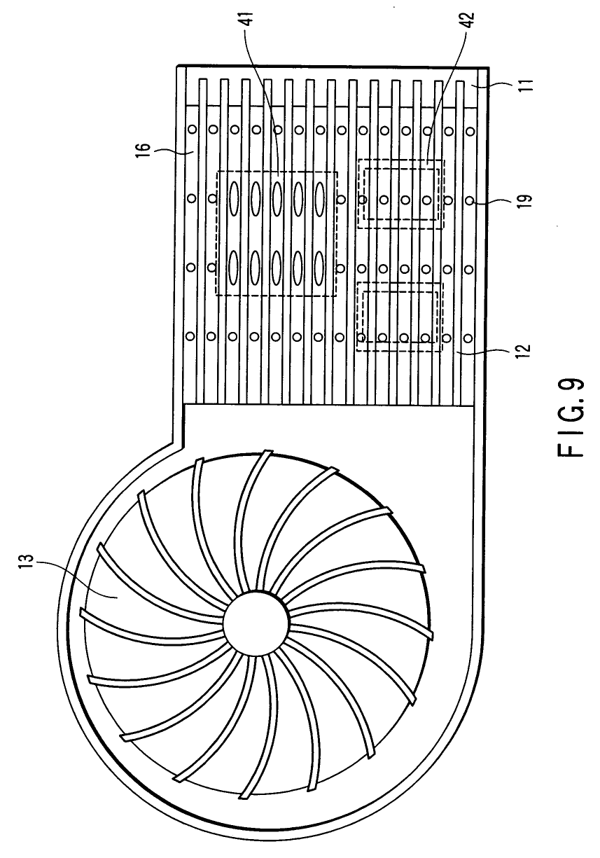

A heat dissipating apparatus according to a third embodiment of the present invention will now be described with reference to FIGS. 7 and 8. FIG. 7 is a plan view schematically showing the configuration of heat dissipating apparatus according to the third embodiment of the present invention.

As shown in FIG. 7, a plurality of through-holes 19 positioned between the adjacent fins 12 are arranged in a direction substantially perpendicular to the flowing-direction of the main fluid stream 7B. The adjacent guide vanes 20 are connected to each other via a connecting section 33. Also, the open area of the through-hole 19 positioned on the upstream side of the fluid stream 7A is larger than that of the through-hole 19 positioned on the downstream side of the fluid stream 7A.

In the third embodiment of the present invention, the main fluid stream 7B flowing within the auxiliary flowing channel 18 is divided at the connecting section 33 so as to permit the same amount of fluid to flow into each of the adjacent through-holes 19. In this case, the flow of fluid from the through-hole 19 into the main flowing channel 17 is not affected by the combination of, for example, the distance from the fin 12 and the arrangement of the through-holes 19 so as to suppress the no uniformity in the amount of fluid flowing from the through-hole 19 into the main flowing channel 17 and, thus, the flow of fluid is stabilized. Incidentally, the effect produced by the connecting section 33 can be further increased if the shape of the connecting section 33 is determined in view of the flowing-direction D1, D2 of the fluid, e.g., if the connecting section 33 is shaped arcuate or streamlined so as to permit a smooth flow of fluid.

Also, in the third embodiment of the present invention, the fins are formed within the auxiliary flowing channel 18. However, it is possible for the fins not to be formed in the auxiliary flowing channel 18 as shown in FIG. 8. In this case, the guide vanes 20 of all the through-holes 19 are connected to each other at the connecting section 33.

Also, the inner pressure of the auxiliary flowing channel on the downstream side in respect of the flow of fluid is higher than that at the inlet port on the side of the fan 13. In the third embodiment of the present invention, the through-holes 19 are arranged such that the open area of the through-hole 19 is gradually diminished toward the downstream side in respect of the flow of fluid so as to prevent the phenomenon that the amount of fluid flowing through the through-hole 19b on the rear side is rendered larger than that of the fluid flowing through the through-hole 19a on the side of the inlet port.

A heat dissipating apparatus according to a fourth embodiment of the present invention will now be described with reference to FIG. 9. Specifically, FIG. 9 is a plan view schematically showing the configuration of heat dissipating apparatus according to the fourth embodiment of the present invention.

In heat dissipating apparatus shown in FIG. 9, a target module 41 to be cooled such as a central processing unit (CPU), which generates a large amount of heat, and a target module 42 to be cooled such as a high-speed memory used in the central processing unit, which generates a relatively small amount of heat, are thermally connected to the base section 11 of the envelope 10. In this heat dissipating apparatus, the through-hole 19L formed in that region of the base section 11 which is thermally connected to the target module 41 to be cooled, which generates a large amount of heat, or formed in the vicinity of the particular region, is designed to have a particularly large open area, compared with the other through-hole 19.

A large amount of heat is generated in that region of the base section 11, which is thermally connected to the target module 41 to be cooled and in the vicinity of the particular region so as to make it necessary to take an effective measure for heat dissipation. In heat dissipating apparatus shown in FIG. 9, the through-hole 19 formed in that region of the base section 11 which is thermally brought into contact with the target module 41 to be cooled, the target module 41 generating a large amount of heat, or formed in the vicinity of the particular region, is allowed to have a large open area so as to make it possible to increase locally the amount of main fluid stream 7B flowing though the through-hole 19 into the main flowing channel 17. If a large amount of main fluid stream 7B flows into the main flowing channel 17, the disturbance 22 of the fluid is promoted, with the result that the boundary layer is unlikely to grow. It follows that it is possible to maintain high heat conductivity.

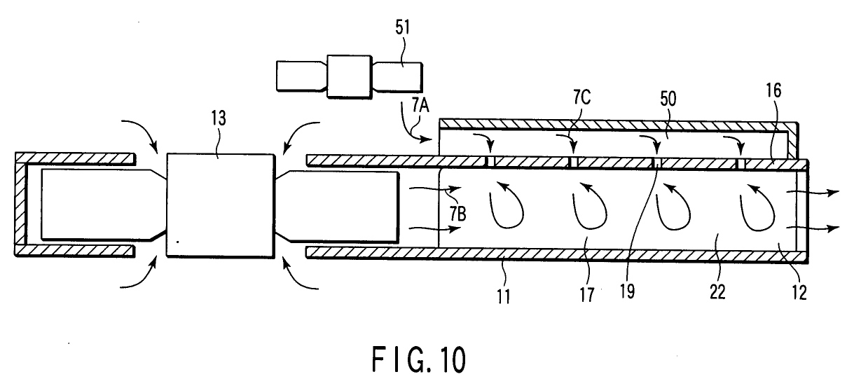

The present invention is not limited to the embodiments described above. It is possible to change the shape, the material and the configuration of heat dissipating apparatus appropriately within the technical scope of the present invention. For example, it is possible to arrange an auxiliary flowing channel 50 outside the envelope, and to utilize, for example, a second fan 51 as the means for supplying the main fluid stream 7B into the auxiliary flowing channel 50, as shown in FIG. 10. Also, the fourth embodiment of the present invention is directed to heat dissipating apparatus in which a central processing unit or a high-speed memory constitutes the target module to be cooled. However, it is apparent that the target module to be cooled by heat dissipating apparatus of the present invention is not particularly limited. For example, it is possible for heat dissipating section of a heat pipe, an electron gun, a laser oscillating section or heat dissipating section of a chiller to be cooled by heat dissipating apparatus of the present invention.

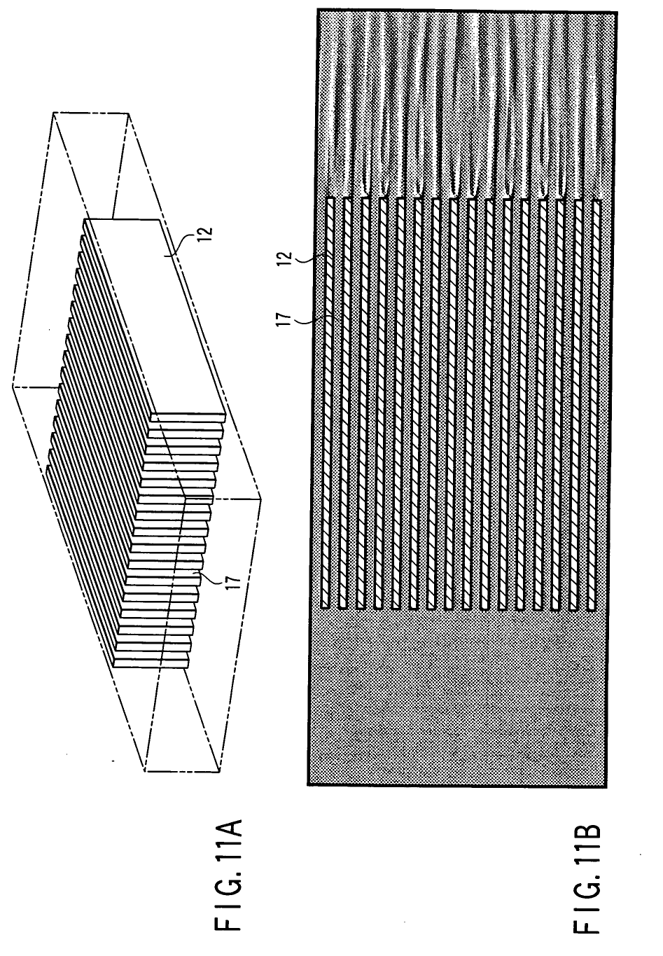

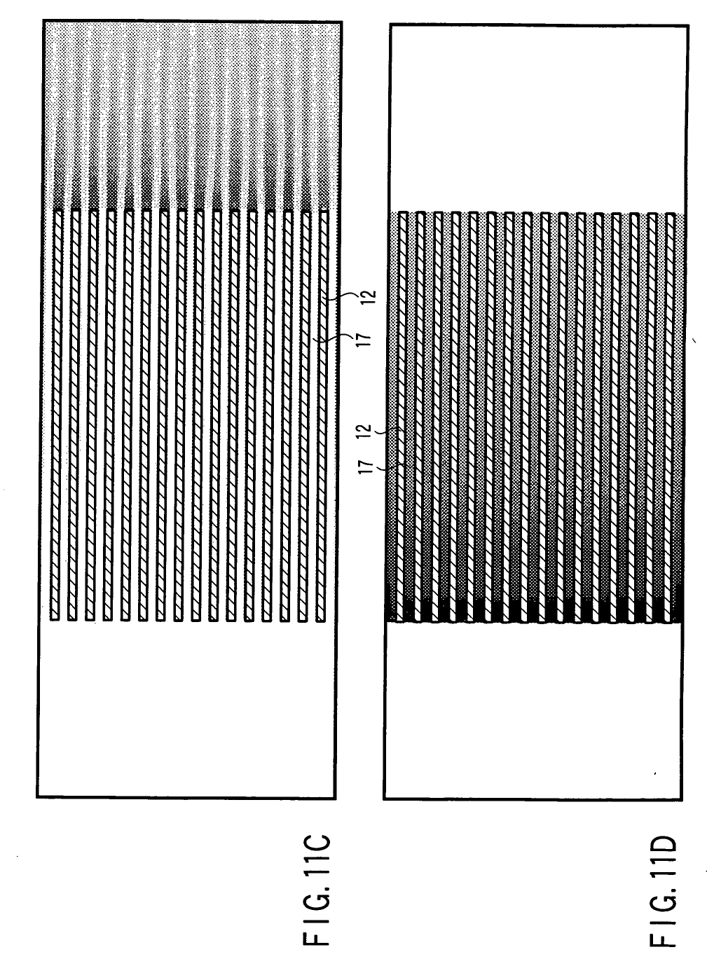

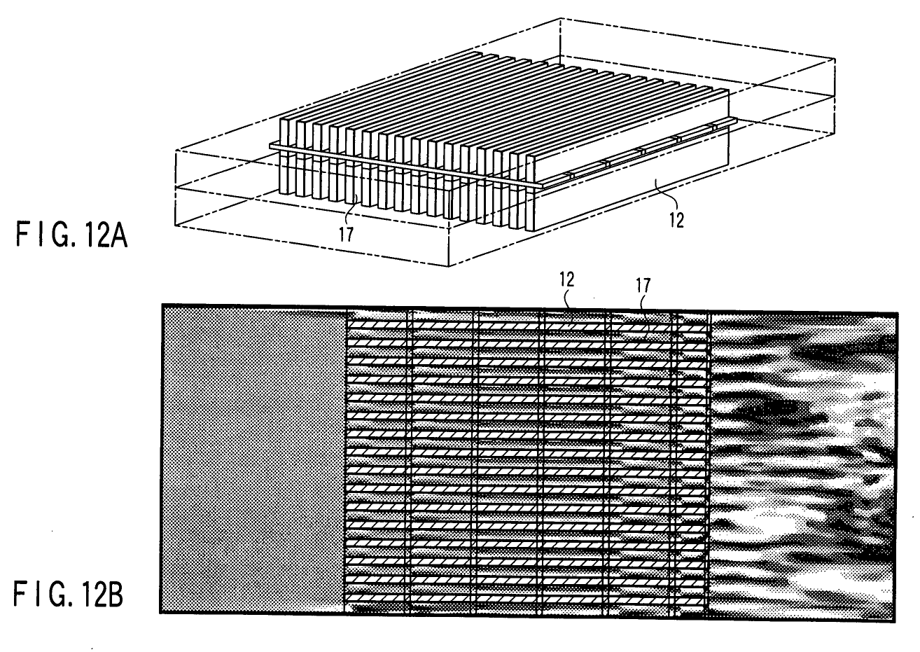

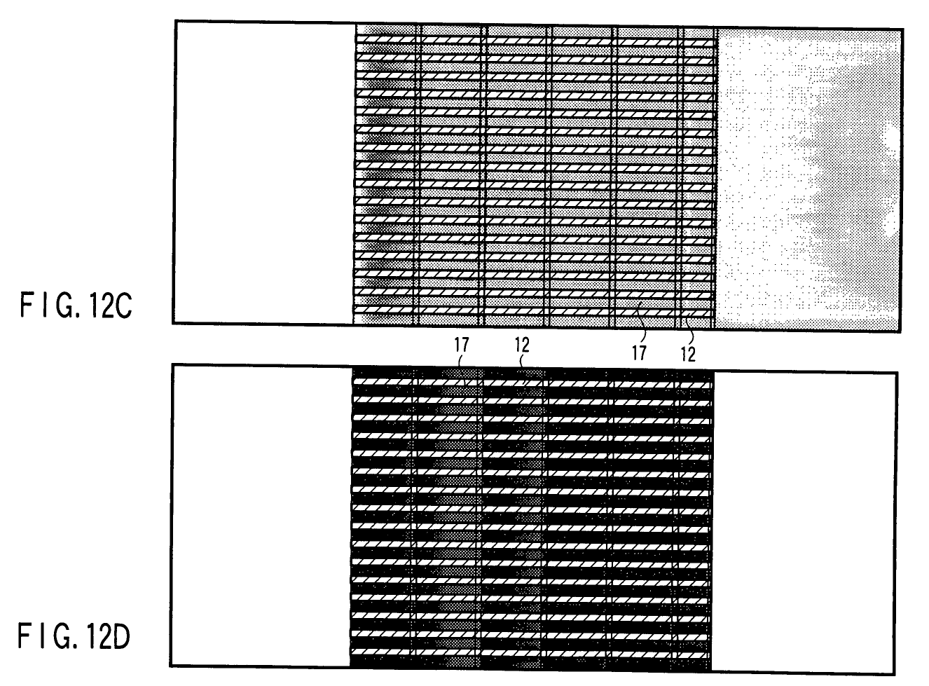

The heat transfer achieved by heat dissipating apparatus according to the embodiment of the present invention and heat transfer achieved by heat dissipating apparatus for the comparative case will now be described with reference to FIGS. 11A to 12D.

As mentioned before, the main object of the present invention is to provide a way to recover heat transfer in the downstream region (thick boundary layer) by decreasing the growth of boundary layer and promoting turbulence in the flow in the downstream region. Here, some results of computation regarding how the flow turbulence results in amplification of disturbance in flow and consequently increases the mixing of fluid in the normal flow direction is presented. These results give a clear understanding of the phenomena, which results in an increase in momentum and heat transport between the hot fin surface and the fluid stream.

FIG. 11A shows the comparative duct configuration of heat dissipating apparatus, which is not provided with a separation wall 16, and FIG. 12A shows the duct configuration of heat dissipating apparatus according to the present invention, which is provided with a separating wall 16 near the top wall. The duct configurations, shown in FIGS. 11A and 12A, have the same dimensions but the different structures as described above. FIGS. 11B and 12B show vorticity distributions in the duct configurations shown in FIGS. 11A and 12A, respectively. In the comparative duct configuration shown in FIG. 11A, substantially no turbulence is produced in the channels 17, but in the duct configuration according to the present invention, as shown in FIG. 12A, turbulences are produced in the channels 17 due to the jet streams. FIGS. 11C and 12C show temperature distributions in the duct configurations shown in FIGS. 11A and 12A, respectively. In the comparative duct configuration shown in FIG. 11A, temperature is gradually increased depending on the flow in the channel from the inlet side to the exit side of the channel due to the boundary layer flow, but in the duct configuration according to the present invention, as shown in FIG. 12A, temperature is gradually decreased depending on the flow in the channels 17 from the inlet side to the exit side of the channel 17 due to the turbulences generated in the main flowing channel 17. FIGS. 11D and 12D show heat transfer distributions in the duct configurations shown in FIGS. 11A and 12A, respectively. In the comparative duct configuration shown in FIG. 11A, heat transfer is mainly generated in the inlet flow region in the channel and gradually lowered from the inlet flow region due to boundary layer flow. However, in the duct configuration according to the present invention, as shown in FIG. 12A, heat transfer is generated in the inlet flow region in the channel and also generated in the another flow regions due to the turbulences generated in the channel.

It can be observed from FIGS. 11B to 11D that the vorticity level of the flow in the ducted fin channel 17 is very low, which means that the turbulence activity of the flow in the ducted fin channel 17 is very low. As a result, the mixing of fluid in the channel downstream is very poor and heat transport between the hot fin surface and the fluid stream decreases due to the growth of flow and a thermal boundary layer downstream. On the other hand, it can be observed from FIGS. 12B to 12D that the vorticity level of the flow is very high, which means the turbulence activity in the flow is very strong due to the interaction of the normal flow jet with the main flow stream. This phenomenon results in appreciable increase in momentum and heat transport between the hot fin surface and the fluid stream by disturbing the boundary layer growth in the channel.

In the embodiment according to the present invention, the mean heat transfer over the fin surface can be increased by nearly 3 times that for the comparative configuration. Also, it can be seen from the following equation that, for a given flow rate, the mean heat transfer coefficient over the fin surface is inversely proportional to the square of the ratio of the primary duct area to the area of the secondary duct formed by the separating wall 12.

$${h}_{av} = \frac{C}{{( {A}_{p} / {A}_{s} )}^{2}}$$

wherein hₐᵥ is the mean heat transfer over the fin surface, C is a constant, which corresponds to the base heat transfer (for a specified flow rate) when the area of the primary duct is equivalent to the area of the secondary duct, Aₚ is the area of the primary duct, and Aₛ is the secondary duct area.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. An apparatus for dissipating heat from a target module to be cooled, comprising:
an envelope having a first flowing channel in which a fluid flows in a first direction and a heat transfer surface along which heat is transferred from the target module to the fluid flows; and
a jet stream supply section configured to supply a jet stream to the fluid flowing in the first flowing channel in a second direction differing from the first direction so as to generate turbulence in the flow of fluid in the first flowing channel, thereby suppressing the growth of a boundary layer in the fluid within the fluid flowing channel.

2. The heat dissipating apparatus according to claim 1, further comprising a guide section configured to guide the jet stream into the first flowing channel.

3. A heat dissipating apparatus for dissipating heat from the target module to be cooled, comprising:
a supply unit configured to supply a flowing fluid; and
an envelope having inlet and outlet ports, configured to guide the flowing fluid from the inlet port to the outlet port, including;
a base section thermally coupled to the target module, configured to conduct heat from the target module;
a lid section configured to defined a flowing space on the base section between the inlet and outlet ports;
a partition plate having a plurality of holes, configured to partition the flowing space into first and second flowing channels to separate the flowing fluid into first and second fluid streams, part of the second fluid stream being jetted into the first fluid stream through the respective holes to generate turbulence in the first fluid stream in the first flowing channel; and
a plurality of fin sections arranged in the first flowing channel on the base section and extended in a direction substantially perpendicular to the base section and between the inlet and outlet ports.

4. The heat dissipating apparatus according to claim 3, wherein the partition plate includes a guide section configured to guide the part of the second fluid stream into the hole.

5. The heat dissipating apparatus according to claim 3, wherein the guide includes a protruding section formed in the edge portion of the hole formed on the partition plate on the downstream side of the second fluid stream.

6. The heat dissipating apparatus according to claim 5, wherein the guide includes a connecting section for connecting the adjacent protruding sections to each other.

7. The heat dissipating apparatus according to claim 3, wherein the partition plate includes a tubular section communicating with the hole, protruding into the second flowing channel, and open to the first flowing channel.

8. The heat dissipating apparatus according to claim 3, wherein the holes formed in the partition plate are arranged in a first flowing-direction of the second fluid stream, and each hole is elongated in the first flowing-direction of the second fluid stream.

9. The heat dissipating apparatus according to claim 3, wherein the hole formed in the partition plate is shaped elliptical, the major axis of the ellipse extending in the first flowing-direction of the second fluid stream.

10. The heat dissipating apparatus according to claim 3, wherein the holes formed in the partition plate are arranged in the first flowing-direction of the second fluid stream such that the hole formed in the upstream side of the fluid has an open area larger than that of the hole formed in the downstream side of the second fluid stream.

11. The heat dissipating apparatus according to claim 3, wherein the hole formed in that region of the partition plate which is positioned to face the target module has an open area larger than that of the hole formed in the other region of the partition plate.

12. The heat dissipating apparatus according to claim 3, wherein the supplying unit includes a fan for guiding the fluid into the first and second flowing channels.

13. A method for cooling a target module, comprising:
allowing a main fluid stream to flow into a main flowing channel of an envelope so as to transfer heat released from the target module to be cooled to the main fluid stream; and
supplying a jet stream into the main fluid stream flowing within the main flowing channel so as to bring about turbulence in the main fluid stream, thereby suppressing the growth of a boundary layer in the main fluid stream within the main flowing channel.

14. The method of dissipating heat from the target module to be cooled according to claim 13, wherein the jet stream is supplied in a direction crossing the flowing-direction of the main fluid stream.
